(19) United States
(12) Patent Application Publication
(10) Pub. No.: US 2016/0205814 A1
(43) Pub. Date: Jul. 14, 2016

(54) INTELLIGENT MODULAR AEROSPACE TECHNOLOGY SYSTEM (IMATS)

(71) Applicant: Edmund David Burke, Santa Maria, CA (US)

(72) Inventor: Edmund David Burke, Santa Maria, CA (US)

(73) Assignee: Space Information Laboratories - c/o Edmund Burke, Santa Maria, CA (US)

(21) Appl. No.: 14/300,233

(22) Filed: Jun. 10, 2014

(51) Int. Cl. H05K 9/00

(52) U.S. Cl. CPC H05K 9/0007

(57) ABSTRACT

As an improvement to the architecture, utility, efficiency, operation, test and checkout, qualification testing and adaptability of an aerospace application system requiring the capability of providing Time/Space/Position Information (TSPI), Data Acquisition/Processing/Relay (DA/P/R), Power Generation/Distribution (PG/D), avionic solutions, navigation, command/data handling and a stand-alone orbiting satellite system technology previously requiring a user to employ and maintain many individual self-contained component boxes to achieve these capabilities, an intelligent, modular, scalable, flexible, stackable, interconnecting, adaptable, reconfigurable, consolidated and interchangeable system hereafter referred to as an Intelligent Modular Aerospace Technology System (IMATS) as shown in an exploded FIG. 1 view is comprised of stackable modules (12) containing a raceway EMI/RFI sealed faraday cage chamber volume (44) and a module EMI/RFI faraday module sealed chamber volume (45) which is capable of containing any device such as a GPS receiver, data processor, telemetry transmitter, battery power system, sensors and the like, all devices being of a totally reconfigurable and open architecture nature while being interchangeably connected in any order, internally interconnected in a plug and play fashion with an internal connector raceway system (24), while the object and advantage of this invention is that it incorporate all attributes necessary to make practical the single integrated box manifestations of complete modularity, scalability, flexibility, stackability, interconnectivity, adaptability, reconfigurability and interchangeability in an intelligent consolidated architecture which allows the capability to rapidly deploy a single box containing all these capabilities versus the existing aerospace systems requiring multiple black boxes to manifest the same functions, with the resultant single box IMATS replacing an array of separate black-boxes previously necessary to provide the same functions, and therefore greatly simplifying design, manufacturing, assembly and testing, and deployability, while sharply reducing cost and simultaneously providing a capability which can equally operate within benign atmospheric conditions, up through the harsh environmental realities of space without any modification.

### CROSS-REFERENCE TO OTHER RELATED APPLICATIONS

This application is the formal patent submission based upon the U.S. Provisional Patent No. 61/574,812 titled, “Intelligent Modular Aerospace System” filed on 8 Aug. 2011, and is a Continuation in Part of “Intelligent Modular Aerospace System”, U.S. application Ser. No. 13/507,773 Published on 14 Feb. 2013.

### BACKGROUND

### Prior Art

The following is a tabulation of some prior art that presently appears relevant:

| Pat. No. | Kind Code | Issue Date | Patentee |
|---|---|---|---|
| 5,534,366 | B1 | 1996 Jul. 9 | Hwang et. al. |
| 6,043,629 | B1 | 2003 Mar. 28 | Ashley et. Al. |
| 7,307,851 | B1 | 2007 Dec. 11 | DiMarco |

### PUBLICATIONS

Jung Soon Jangt and Claire J Tornlint

“Design and Implementation of a Low Cost, Hierarchical and Modular Avionics Architecture for the Dragon Fly UAVs”

AIAA Paper 2002-4465.

Rene L. C. Eveleens,

“Open Systems Integrated Modular Avionics- The Real Thing”

National Aerospace Laboratory NLR, Netherlands, 2006

Current aerospace application systems operating for the purpose of providing Time/Space/Position Information (TSPI), Data Acquisition/Processing/Relay (DA/P/R), wireless communication, Power Generation/Distribution (PG/D), avionics, navigation, command and data handling require a user to employ and maintain many individual self-contained component boxes employing singular individual independent functions, hereafter known as black-boxes for each individual desired TSPI, DA/P/R, wireless communication, avionics, command and data handling or PG/D function. The downside of this antiquated approach is that when a vehicle using such a fractionated and federated suite of aerospace hardware requires an incremental or full upgrade to a particular TSPI, DA/P/R, wireless communication, avionics, navigation, command and data handling or PG/D system, it often requires years of development and a vast amount of funding to modify that TSPI, DA/P/R, wireless communication, avionics, navigation, command and data handling or PG/D hardware suite aboard that particular vehicle so it can meet its new and changing requirements.

Additionally, the many black-boxes comprising each single TSPI, DA/P/R, wireless communication, avionics, navigation, command and data handling or PG/D capability forces a customer into the extremely high cost of redeveloping and environmentally qualifying each of the many separate black-boxes which are part of the individual TSPI, DA/P/R, wireless communication, avionics, navigation, command and data handling or PG/D system, consistently resulting in an unnecessary and extremely large cost for an even incremental or minimal upgrade. Additionally, each black box is typically only usable on a single class of vehicle, and if not space-qualified it cannot be used in a space application, and is therefore restricted for use within atmospheric benign conditions. Conversely, a typical space-qualified black-box would be cost prohibitive to employ on an aircraft or a vehicle only used in benign atmospheric conditions from the earth's surface on up into typical aircraft altitudes.

To the best of our knowledge, no prior art exists regarding an overall self-contained aerospace system such as an Intelligent Modular Aerospace Technology System (IMATS) functioning in any TSPI, DA/P/R, wireless communication, avionics, navigation, command and data handling or PG/D role in one single integrated and consolidated box exhibiting the qualities of complete modularity, scalability, flexibility, stackability, interconnectivity, adaptability, reconfigurability and interchangeability in an intelligently consolidated manner which allows a customer to rapidly or even possibly meet a new mission requirement with their currently employed multiple black-box systems, and certainly, no federated avionics suite of functional black boxes exist which can instantly be transferred into and utilized in any vehicle operating in all environments from benign atmospheric to the harsh and unforgiving environment of space, without costly modifications which would make the reality of this spectrum of applications cost prohibitive.

There are however a very limited number of inventions illustrating a modular type concept by addressing modular battery packs, modular control electronics for batteries, and a method of modularly mounting numerous circuit cards within an EMI/RFI resistant cabinet. A modular battery pack invention by Hwang et. Al. only concerns itself with the physical mounting of interfaces for a battery's easier replacement. The modular control electronics for the battery invention of Ashley et al. only concerns itself with the modular control of charging each battery cell to protect the batteries and optimize their performance. An integrated modular avionics cabinet by DiMarco details an enclosure capable of consolidating various circuit cards adjacent to each other within individual modules which in-turn are mounted within an externally EMI/RFI resistant cabinet, complete with cooling holes for each of the modules, and also providing connectors on the back of each module for convenient data distribution. While fine for its intended purpose of operating in an external EMI/RFI environment, it is not designed to handle the internal EMI/RFI environment generated if they attempted to co-locate RF, processor, data communication and I/O, and power functions internally within this box, and subsequently limiting the utility of the box for use with only a partial capability which would then require external separate multiple enclosures to handle the RF, processor, data communication and I/O, and power separately, and thus not making it possible to achieve a truly single unit integrated modular avionics (IMA) system but a federated IMA system for use in any desired scenario as demanded by the IMATS invention. Additionally, DiMarco's enclosure is not built in any possible way to withstand the missile or rocket launch environments of shock and vibration or thermal, nor operate in the vacuum of space due to its reliance upon convection cooling as evidenced by his cooling holes for circulation, which would do nothing where air does not exist. Papers by Jung Soon Jangt/Claire J Tornlint and Rene L. C. Eveleens describe systems which while hint at a modular approach, are only partially modular and integrated while falling completely short at solving the problems inherent in combining all components such as RF (wireless communication), Power, processor, data communication and I/O, and navigation functions into a single space-qualified stack, and additionally have not even considered the complexities involved with passing Electromagnetic Interference (EMI)/ Radio Frequency Interference (RFI) and thermal considerations inherent with a totally integrated modular system containing all functions necessary to serve in a true and complete avionics or other aerospace technology role, all in a single box. Due to the nature of these systems, none of them can be adapted to the extent of the intent and demands that are required by this invention for the following reasons:

(a) While not even exhibiting the qualities and benefits of a single-box solution, no federated black-box aerospace hardware and avionics systems incorporate methodology for isolating/combining/reconfiguring internal components either physically or via software command in an integrated fashion in the event that mission requirements change in real-time.

(b) The failure of a single black-box in a federated aerospace hardware and avionics system has the high likelihood of jeopardizing a mission resulting in a system failure, as it is not possible to automatically protect on a complete system level where workarounds could be automatically implemented because of the proprietary nature of each individual black-box making up the system.

(c) There is no system or method specified therein which is available to provide real-time monitoring/feedback on the health status of the contents of all components within their black-box, semi-integrated configuration.

(d) The limiting architecture and design of existing systems, black-box or semi-integrated precludes the rapid integration of external sensors or other sources desired to augment internal components or complete functions.

(e) No capability exists for integrated real-time data gathering within the federated avionics system subsets that comprise a capability synthesized by the interaction of two or more components or black-boxes within a wholly defined configuration.

(f) In addition to inefficiencies that accompany the limiting factors encountered in fielding today's federated/only partially integrated modular aerospace hardware and avionics systems, their ‘antiquated upon delivery’ nature also suffers from significant operations/maintenance issues and costs required to recondition and service components within the federated black-boxes which at best comprise a semi-integrated federated configuration.

(g) The closed and proprietary nature of today's federated/only partially integrated modular aerospace and avionics hardware systems is firmly based upon obsolete technology with long-lead time architecture by its very nature, and is often size, weight and power (SWAP) excessive when compared to the rapidly evolving technologies which cannot be integrated and consolidated without major redesign and a prohibitive cost.

(h) Presently federated/only partially integrated modular aerospace hardware and avionics systems are limited to their individual unique manufactured unit, and do not allow for their rapid reconfiguration to a larger/smaller capacity, either physically or electronically.

(i) All present federated/only partially integrated modular aerospace hardware and avionics systems negate the possibility of morphing their configuration into a modular “LEGO” type system, either in a physical or electrical arrangement, thus increasing their design, implementation and qualification costs.

(j) Extreme launch environments cause present federated/only partially integrated modular aerospace hardware and avionics systems with multiple black-boxes to undergo costly individualized pre-qualification testing to mitigate potential problems from surfacing during the operational employment of their fully fractionalized system.

(k) Present federated/only partially integrated modular aerospace hardware and avionics system architectures do not allow for a larger method of control aside from the immediate systems they are employed within, thus eliminating the possibility of mesh network control and redundant fail-over switching.

(l) Currently deployed federated/only partially integrated modular aerospace hardware and avionics systems are incapable of providing integrated real-time monitoring of health and status, thus precluding the capability to head-off and work-around an internal failure before it happens, which would not even be possible because of the federated nature of the system.

(m) Federated/only partially integrated modular aerospace hardware and avionics systems with multiple black boxes as currently arranged in aerospace systems are not capable of being quickly combined with other system hardware in real-time in the event of a change in mission requirements or a change in external interfaces.

(n) No fail-over/safe system exists to insure functionality of the overall system if a single component or module fails within a distributed system of partially integrated, federated black box system.

(o) Space rated environmental qualification testing is complex and plagues all multiple black-box designs, forcing the designer into expensive qualification re-testing programs that have major schedule and cost impacts even if a tiny component and/or subsystem within a black-box is removed, changed or modified.

(p) Today's federated/only partially integrated modular aerospace hardware and avionics systems comprised of multiple black-box combination systems cannot accommodate the capability for an integrated level predictive performance in accordance with the number of cycles they have been subject to.

(q) Impacts of size and weight constantly arise during employment of existing multiple black-box systems, often resulting in the sacrifice of other mission capabilities.

(r) Query, reset, work-around, initializing, conditioning or reconfiguring is not possible within the confines of any of these prior art inventions, nor is it available at all within the industry.

(s) Current federated/only partially integrated modular aerospace hardware and avionics systems cannot and do not combine processor, data communication and I/O, RF (wireless communication) and power devices in one modular, stackable and reconfigurable system that can pass rigorous environmental (thermal, random and sine vibration, shock, etc.) and EMI/RFI testing.

(t) Present federated/only partially integrated modular aerospace hardware and avionics systems are designed and built for two separate and distinct realms of operation, that of being used within the benign atmospheric conditions or the harsh environment of space, while none can accommodate both environments in a practical way.

(u) The federated/only partially integrated modular aerospace hardware and avionics systems today cannot be integrated into a single unit for passing space qualification testing without a redesign from the ground-up.

(v) At best, all proposed and not even yet fielded semi-modular systems are not designed with any consideration for shock, vibration or EMI, and are not able to accommodate RF devices internally, thus are making false claims as to being completely scalable, modular etc., and nowhere approximates the intent or capabilities of this invention.

(w) No proposed modular systems incorporate individual EMI chamber modules that interlock for creating an instant Faraday Cage and shock/vibration immune enclosure that is expandable without any practical limit.

(x) All present federated/only partially integrated modular aerospace hardware and avionics systems employ an interconnection means that is external to the individual circuit boards or black-boxes, and thus manifest a definite and inherent weakness that cannot be surmounted if full space qualification testing is desired.

(y) Current federated/only partially integrated modular aerospace hardware and avionics systems cannot be crossed-over in application from use within benign atmospheric conditions all the way through the extreme environment of space.

(z) Federated/only partially integrated modular aerospace hardware and avionics systems in space are vulnerable to external physical attack due to their large size that results in the overall sum of individual box sizes.

### SUMMARY

The summation of all these lacking capabilities serve to indicate why no prior art regarding a self-contained, truly integrated modular aerospace hardware and avionics system exists which exhibits the qualities of complete modularity, scalability, flexibility, stackability, interconnectivity, adaptability, reconfigurability and interchangeability in a singular integrated unit that forms an intelligent consolidated architecture incorporating the features of RF (wireless communication), processor, data communication and I/O, EMI/RFI and power which can instantly function within benign atmospheric conditions, and up through the atmosphere into the vacuum and intense temperature extremes of space, as well as the high shock and vibration environment of missile/rocket transit in-between. As such, without the advancements and innovations detailed in this invention, the aerospace industry will be forever relegated to the same ‘black box syndrome’ where the individual federated aerospace hardware and avionics systems with multiple black-boxes are costly and vehicle specific when used within/without the atmosphere, and take up unnecessary space and weight with a costly price tag. Additionally, the methods proposed by Jung Soon Jangt/Claire J Tornlint and Rene L. C. Eveleens and DiMarco actually do nothing to advance the art whereby they left out the most important and to this day unsolvable methods of integrating RF (wireless communication) functions with power, processor, I/O, EMI and RFI isolation into a single unit which can be instantly used within or outside the atmosphere without any modification and instantly pass space qualification testing for operating in any environmental regime.

### ADVANTAGES

Accordingly, the main intention, object and advantage of this invention is that it incorporate all attributes necessary to make practical the qualities of modularity, scalability, flexibility, stackability, interconnectivity, adaptability, reconfigurability, consolidation and interchangeability in a single unit combining the functions of RF (wireless communication), processor, data communication and I/O, EMI/RFI isolation (radiative and conductive emissions), and power which can instantly function within benign atmospheric conditions, and up through the atmosphere into the vacuum and intense temperature extremes of space, as well as the high shock and vibration environment of missile/rocket transit in-between these locations.

Employment of the approach detailed by this invention allows for the rapid development and fielding of many new aerospace systems in addition to the retrofitting of older systems which can realize the multiple advantages in cost and efficiency associated with the transition to IMATS for achieving the most efficient way to function in the TSPI, DA/P/R, wireless communications, avionics, navigation, command and data handling and PG/D realm, which ultimately enables the transition from a ground based infrastructure to a space-based infrastructure.

In addition to these clear advantages regarding our perception of the most practical approach that a completely modular, scalable, flexible, stackable, interconnected, adaptable, consolidated and interchangeable single box aerospace system should take the form of, this invention also benefits from the following important advantages:

(a) A complete and comprehensive intelligent capability is integral to the IMATS that isolates, combines, and reconfigures internal components in any module and in concert with the functions in all associated modules in the event of an internal system failure or real-time mission change.

(b) The ability to provide backup and fail-over modes between stackable and reconfigurable modules due to their non-proprietary individual nature and interconnectedness allows for a reliability standard never-before achieved to be inherent in all avionics/aerospace systems.

(c) The employment of a real-time monitoring and feedback methodology exists between all interconnected modules to insure that all systems are performing as expected through all mission phases.

(d) The single integrated and consolidated box approach allows for instant communication access between any internal and/or external sources or sensors that are required to interface with any particular component or system within the defined integrated modular and scalable box configuration.

(e) An immediate methodology is employed amongst any and all components within all modules in any configuration to allow for data to be gathered simultaneously or in an integrated fashion from any system or subsystem down to the component level within the defined box configuration.

(f) The complete open, modular, stackable and reconfigurable architecture allows for new state-of-the-art components to be substituted and installed within the defined system at any time, insuring a customer will always have the ability to receive the latest technological capability as it is fielded, and to have the option for upgrade at any time, thus making possible the greatest capability at the lowest price with the greatest life-cycle cost efficiency.

(g) The smartly integrated commercial off-the-shelf components are of the most recent manufacture and leading-edge capability imposing the most minimum size, weight, and power footprint of any components possible on the market today.

(h) The completely flexible architecture enables an immediate physical or electronic reconfiguration capability for either testing or employment at any time, allowing for scaling up or down as a customer requires.

(i) The instantaneous connection capability both electronically or mechanically between modules allows for an immediate modular arrangement or rearrangement at any time, and gives the ultimate flexibility to a customer who needs to keep design, implementation, and qualification costs to an absolute minimum while gaining the most comprehensive capability possible.

(j) The demonstrable capability evident in employing one box to do the job of many has far reaching scales of economy in weight reduction, qualification testing, troubleshooting, fielding and life cycle cost.

(k) Interconnection and communications flexibility allow for monitoring or control from any location in any configuration including any networking capabilities wishing to be exercised or employed on an operational basis.

(l) Fail-over scenarios are integral to the internal system workings, and can circumvent a possible failure from actually happening while status is being observed from an external viewpoint.

(m) Whenever any external events may trigger a change in flight planning or deployment, the system quickly and efficiently is capable of instantly adopting all new requirements and manifesting them into a newly defined set of parameters resulting in a redefined system in real-time which is capable of meeting all newly defined mission criteria and needs.

(n) The redundancy inherent in the system ensures that practically no single failure can occur which would result in the loss of a mission.

(o) The simplified single box approach allows for the single most efficient way to conduct any and all qualification/re-qualification testing at any level from a component piece through a completely integrated and consolidated single box system, independent and irrelevant of any new components that may or may have not become a new part of the newly defined system.

(p) The historical testing and fielding of this integrated and consolidated single box system has a large reliability database substantiating all components and their respective placements within the defined borders of the system at all levels, while absolutely minimizing the complexities involved of introducing new components.

(q) Impressive amounts of expensive vehicle real estate suddenly become available when employing this single box approach, allowing for notable system performance increases and accommodation of new payload capabilities while offering notable increased ease of system-wide employment.

(r) Complete access to all box functions are available via a direct data/telemetry monitoring capability on the ground or as the vehicle is in flight, thus giving increased confidence in all aspects of mission performance, while allowing for complete control or monitoring at any desired timeframe.

(s) This single-box approach combining all computational processing, RF, communications and power into one modular and reconfigurable stackable system enables the unit to undergo all environmental testing and flight certifications in a streamlined and expeditious way.

(t) The IMATS can equally operate in benign atmosphere conditions or the vacuum of space without any modification while being very inexpensively suited to both locations instantly.

(u) The integrated nature of the IMATS is such that it undergoes only one Space Qualification trial as an integrated unit, as opposed to multiple black box systems which must undergo Space Qualification testing on each and every black-box, with ripple effects often time occurring when one box is changed out, it then requiring that other boxes be changed out and re-qualified.

(v) The essence of this invention is that it is completely designed for EMI/RFI, incorporating RF transmitting and receiving devices internally with processor, data communication and I/O, and power present in the same integrated box, and as such is the first truly integrated modular aerospace system containing all necessary components of a complete aerospace technology or avionics application suite.

(w) The revolutionary design of using tongue in groove for interlocking the modules creates a structure that is completely shock and vibration tolerant, in addition to providing a instant faraday cages when two modules are assembled together.

(x) The internal interconnecting raceway between modules allows to the outer surface of the invention to remain wire-free, while simultaneously shielding all wires within an internal faraday cage that further allows for the simplest passage of space qualification testing.

(y) This invention can be equally utilized within benign atmospheric conditions on any vehicle, terrestrial or not, or the extreme environment of space without any modification, thus allowing for simple low-cost applications to leverage the robust nature of the truly integrated modular approach while achieving the same level of functionality it would cost orders of magnitude more of if attempted with existing black-boxes.

(z) The applicability of this open, modular and reconfigurable approach allows for it to be used as a stand-alone satellite bus/system which is small and is as robust as any large satellite equivalent, allowing for smaller undetectable satellites to proliferate space which are much more survivable due to their small and easily replenishable nature.

### DRAWINGS

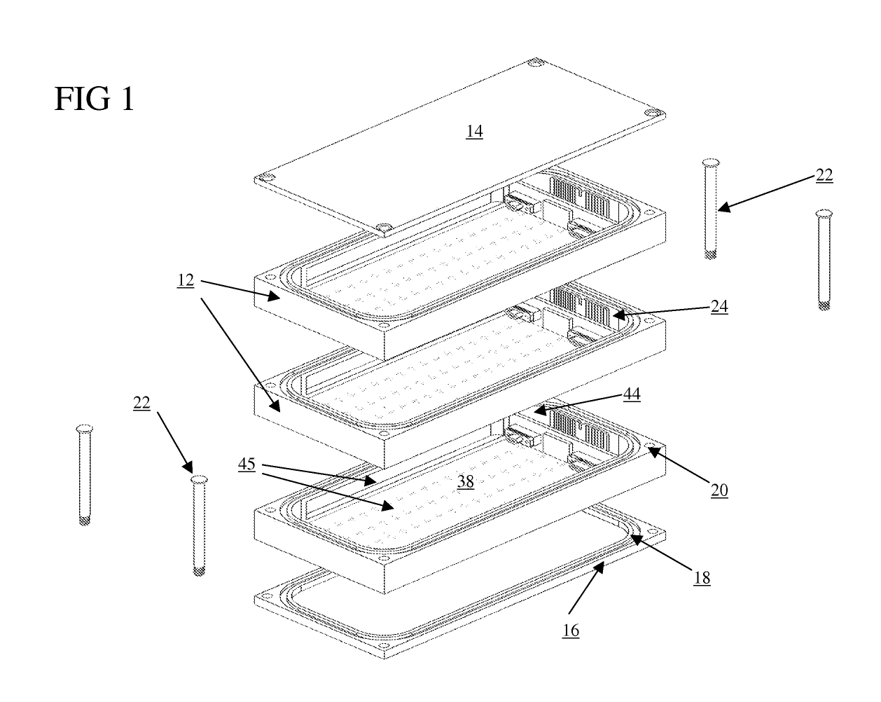

### FIGS. 1-8

FIG. 1. is a three dimensional drawing which illustrates the main exterior and interior surfaces of the IMATS modules which can be of varying height, along with their interconnecting backplane connector system and cover with bolt-down methodology.

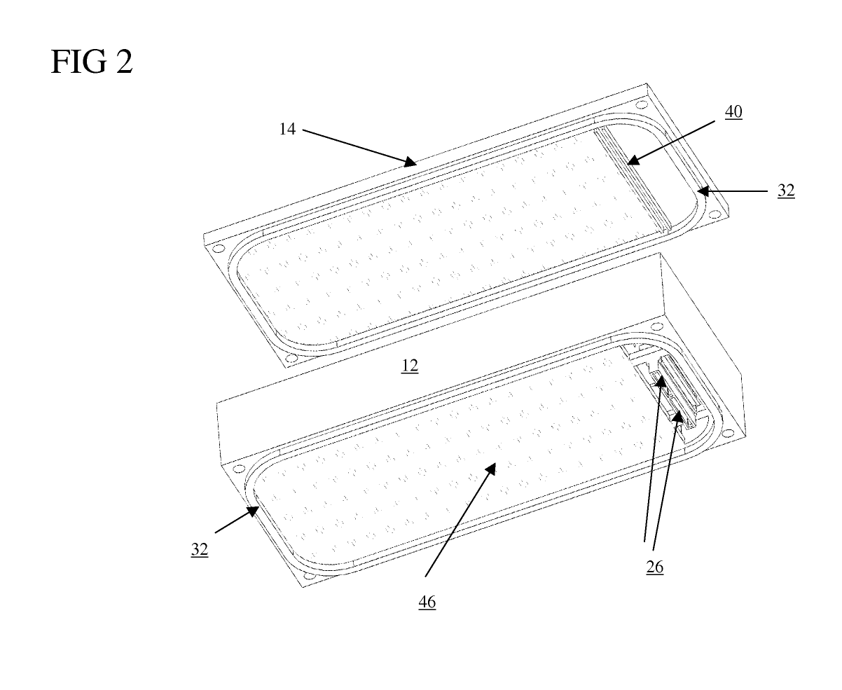

FIG. 2. is a three dimensional drawing showing the underside of a cover and a typical module, along with a view of the underside of an interconnecting backplane connector.

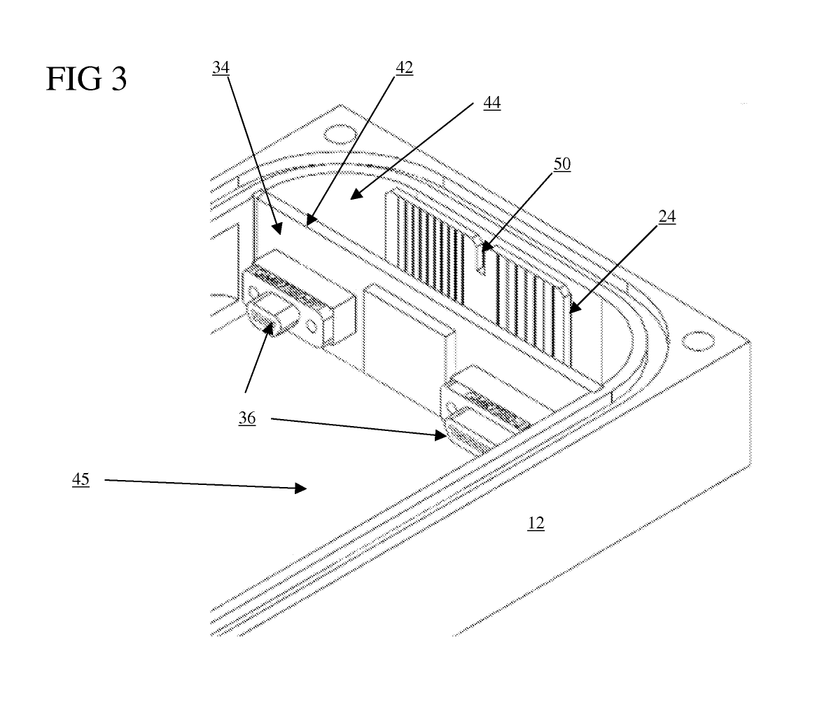

FIG. 3. is a three dimensional close-up top view of the interconnecting backplane connector system as it sits within a module.

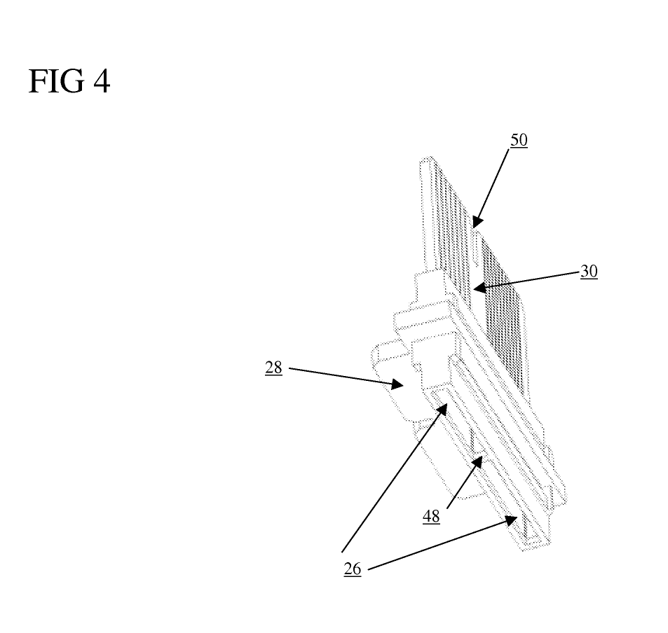

FIG. 4. is a three dimensional close-up view of a connector angled the same way as in FIG. 2.

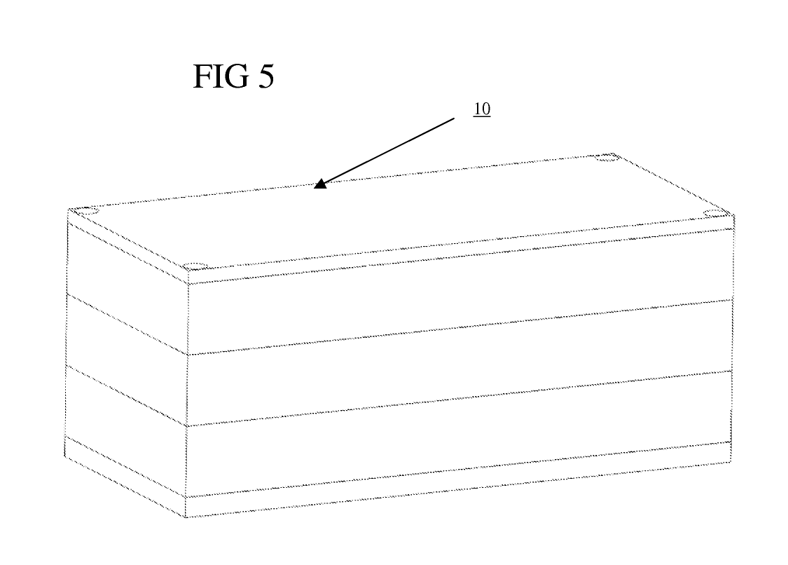

FIG. 5. is a three dimensional bolted together example of an IMATS.

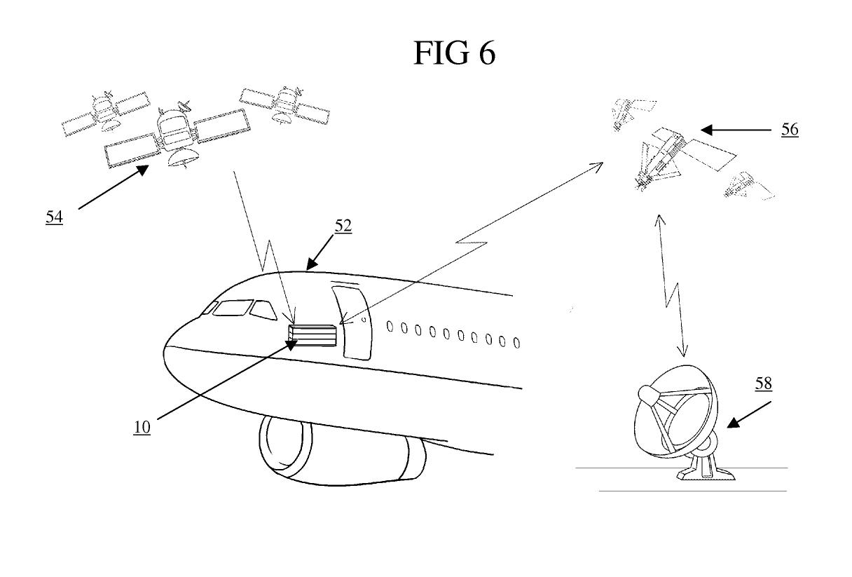

FIG. 6. is a three dimensional view of the assembled IMATS box of FIG. 5 deployed in a typical representative aircraft.

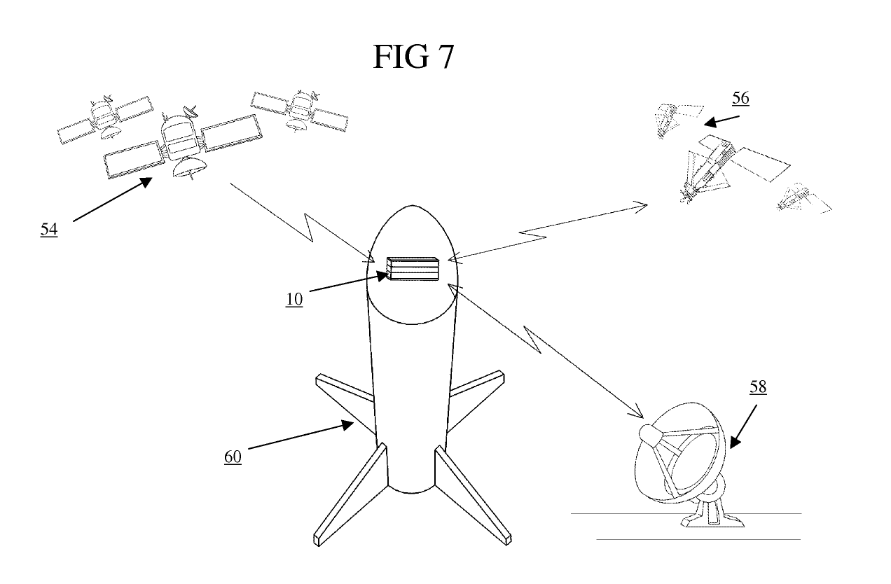

FIG. 7. is a three dimensional view of the assembled IMATS box of FIG. 5 deployed in a typical representative missile or rocket.

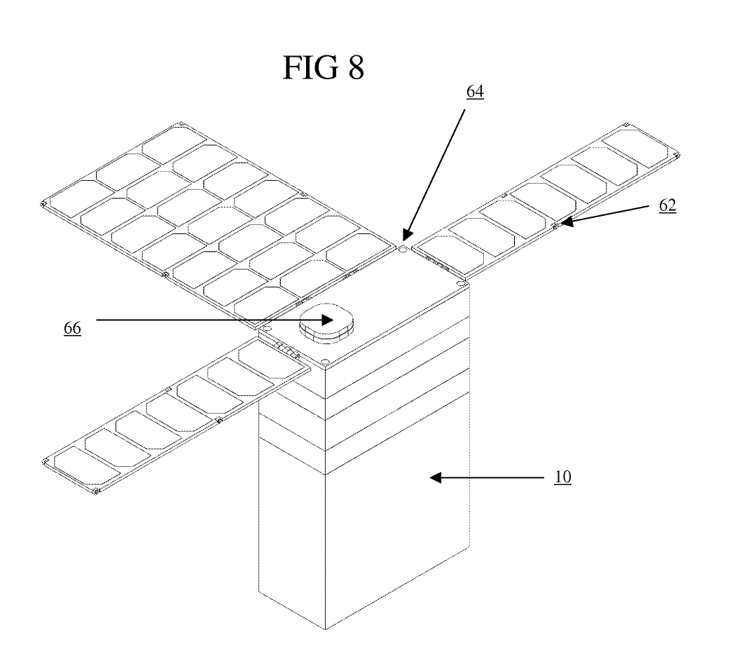

FIG. 8. is three dimensional representative view of the IMATS box of FIG. 5 only with modules of different heights and the entire unit adapted to be a satellite with solar panels deployed.

### REFERENCE NUMERALS

10 intelligent modular aerospace technology system

12 stackable module

14 module lid

16 module stack base

18 module female sealing groove

20 module bolt hole

22 module bolt

24 internal connector raceway system

26 internal raceway female connection

28 raceway wall male connection interface

30 internal raceway male connection

32 module stacking tongue

34 raceway wall female connection interface

36 raceway wall module connectors

38 module floor

40 raceway wall female sealing groove

42 raceway wall male sealing tongue

44 raceway sealed chamber volume

45 module sealed chamber volume

46 module floor underside

48 internal raceway male connection guide

50 internal raceway female connection guide

52 representative aircraft platform

54 GPS satellite constellation

56 generic relay satellite constellation

58 standard telemetry ground receiving system

60 representative missile/rocket platform

62 representative solar panels

64 intelligent modular satellite system

66 representative antenna

### DETAILED DESCRIPTION

### FIGS. 1-8

An intelligent modular aerospace technology system 10 as illustrated in FIGS. 1-8 is comprised of any number of stackable modules 12 of same or varying heights, electrically interconnected via an internal connector raceway system 24 within raceway sealed chamber volume 44 and physically via module stacking tongue 32 and module female sealing groove 18 and raceway wall female sealing groove 40 and raceway wall male sealing tongue 42 in addition to module bolt holes 20 and module bolts 22 forming a complete integrated and sealed intelligent modular aerospace technology system 10 as illustrated in FIG. 3 where module lid 14 interfaces with the top of stackable module 12 and beneath stackable module 12 with module stack base 16 by utilizing the same module stacking tongue 32 and module female sealing groove 18 as occurs between any stackable module 12. When a stackable module 12 is secured on top of another stackable module 12, module floor underside 46 seals the top of another module 12 in the exact manner that module lid 14 does, forming module sealed chamber volume 45, while simultaneously if two stackable modules 12 are connected, internal connector raceway system 24 connects to another internal connector raceway system 24 via inserting internal raceway male connection guide 48 into internal raceway female connection guide 50 in conjunction with securely fitting internal raceway male connection 30 into internal raceway female connection 26.

Internal to module 12 is module floor 38 forming a sealed chamber when either another module 12 is secured above it, or a module lid 14 is secured above it. All electrical connections into a chamber are via raceway wall module connectors 36 which are part of raceway wall female connection interface 34 that connects with raceway wall male connection interface 28.

An intelligent modular aerospace technology system 10 as illustrated in FIG. 6 shows its versatility with instant unmodified placement upon a vehicle operating within a representative aircraft platform 52 which has direct communication paths to GPS satellite constellation 54, generic relay satellite constellation 56, and standard telemetry ground receiving system 58.

An intelligent modular aerospace technology system 10 as illustrated in FIG. 7 shows its versatility with instant unmodified placement upon a representative missile/rocket platform 60 which has direct communication paths to GPS satellite constellation 54, generic relay satellite constellation 56, and standard telemetry ground receiving system 58.

An intelligent modular aerospace technology system 10 as illustrated in FIG. 5 and FIG. 8 is instantly adaptable into becoming intelligent modular satellite system 64 with the addition of representative solar panels 62 and representative antenna 66.

### OPERATION

### FIGS. 1-8

Intelligent modular aerospace technology system 10 as illustrated in FIGS. 1-8 has solved the design and operational complexities involved with finally manifesting a single box which is capable of operating equally as efficiently within benign atmospheric conditions as it does in the harsh environment of space, including transit into space aboard any missile or rocket. The manifestation of the first truly modular, stackable, scalable, flexible, interconnectable adaptable, reconfigurable, consolidated and interchangeable approach in a single unit combining the functions of RF (wireless communication), processor, data communication and I/O EMI/RFI, power with a EMI/RFI chamber design instantly allows for a manifestation of complex interchangeable hardware, software and firmware integrated and consolidated together in a manner to allow never-before combined functions such as Time/Space/Position Information (TSPI), Data Acquisition/Processing/Relay (DA/P/R), wireless communication, avionics, navigation, command and data handling and Power Generation/Distribution (PG/D) to reside in a single unit. Additionally, the combining of all these functions to comprise the intelligent modular aerospace technology system 10 allows for unprecedented efficiencies in design, manufacture and space qualification testing to occur on a one-box system level, and provides for all components and capabilities within stackable modules 12 to be instantly accessible for any reason by simply removing module bolts 22 and subsequently easily separating any stackable module 12 from another, or removing module lid 14 from the top of a stackable module 12 if it is the top module stackable module 12. Stackable module 12 can be of varying height depending upon the needs of the user, with internal connector raceway system 24 being variable to any measurement needed to support any varied stackable module 12 height. Any components with functions such as RF (wireless communication), processor, data communication and I/O EMI/RFI, power, navigation sources (GPS receiver, INS, IMU, etc.) can be placed in any module, and instantly interfaces with standard communication protocols to raceway wall module connectors 36.

The innovations at the heart of the intelligent modular aerospace technology system 10 make obsolete the need to employ many distributed/federated black boxes which today results in a huge price tag for development, unnecessary size and weight implications, qualification testing on many boxes instead of just one, and the need to always have RF, processor and power devices separated, stackable modules 12 are each the equivalent of one black-box which would only provide one function of the array necessary in an aerospace hardware suite, those functions, amongst others are RF (wireless communication), processor, data communication and I/O EMI/RFI, power, and other navigation sources (GPS receiver, INS, IMU, etc.) input. By combining all these functions individually, each in a stackable module 12, one quickly and simply achieves the first truly modular, stackable, scalable, flexible, inter-connectable, adaptable, reconfigurable, consolidated and interchangeable single box that does all functions necessary in an aerospace hardware suite, while not restricting its use to being only of avionics, but also includes but is not limited to any TSPI, DA/P/R, wireless communication, navigation, command and data handling, PG/D function or even as a stand-alone satellite which can be networked in space with an unlimited number of other similar or different satellites and ground stations. The EMI/RFI chambers that instantly manifest as module sealed chamber volume 45 upon mating two stackable modules 12 or a stackable module 12 with a module lid 14 allow for the first time mixing of RF (wireless communication), processor, data communication and I/O EMI/RFI, power, GPS Rx/INS/IMU navigation input in one singly space qualifiable box which can be used instantly on a vehicle operating in benign atmospheric conditions up through and including the harsh environment of space, and without any increase in cost due to the innovative design which is applicable and cross-cutting for use in all environments on practically any aerospace or other vehicle type. The tongue in groove design exemplified and applied with module stacking tongue 32, module female sealing groove 18, raceway wall male sealing tongue 42 and raceway wall female sealing groove 40, all in combination with internal connector raceway system 24 create the necessary EMI/RFI chambers necessary to combine for the first time mixing of RF, processor, data communication and I/O EMI/RFI, power, GPS Rx/INS/IMU navigation input in one singly space qualifiable box which can be used instantly on a vehicle operating in benign atmospheric conditions up through and including the harsh environment of space, and without any increase in cost in any environment due to the innovative design which is applicable and cross-cutting for on practically any aerospace or other vehicle type. FIGS. 6, 7 and 8 clearly show how simple it is to use an intelligent modular aerospace technology system 10 on a representative aircraft platform 52, a representative missile/rocket platform 60, or even as a standalone intelligent modular satellite system 64. In the aircraft and missile/rocket application, the same GPS satellite constellation 54 is employed as is the same generic relay satellite constellation 56 and the same standard telemetry ground receiving system 58. The use of the architecture described in the intelligent modular aerospace technology system 10 when applied to an intelligent modular satellite system 64 will dominate and change the satellite industry by providing the capability to build satellites which are at least as, or more robust as the currently employed ones which cost orders of magnitude more money to design and develop due to their proprietary nature, and are not nearly as efficient to integrate and deploy in a responsive manner due to their unique individualistic black-box designs integrated on a case-by-case basis.

### ADVANTAGES

The above description distills the essence of the invention into the key component and integrated capabilities which illustrate the unprecedented qualities of complete modularity, scalability, flexibility, stackability, interconnectivity, adaptability, reconfigurability and interchangeability in an intelligent consolidated architecture into a single integrated aerospace technology and avionics system for multiple applications which takes the place of many federated ones by combining functions never contemplated to combine before into one single box structure, and is capable of operating in a space or earth environment instantly without any modification, with more detailed qualities and capabilities being further described as follows:

1) A fail-safe design permeates all aspects of the IMATS components, including the integral system approach whereby internal and external structures function together in a deliberate synergistic interactive manner as a single unit.

2) The design flexibility and implementation of the system allows for any module configuration to employ safeguards which are interactive with any other module configuration which in turn absolutely minimizes the possibility of any RF conductive and radiative emissions to damage functionality of the electronics (processor, data communication and I/O, etc.), wireless communication and navigation devices inside and/or outside the contained module area.

3) Health and Status data of all component monitor points continually provides a live view of the unit's internal workings through all employment scenarios, and allows for dynamic reconfiguration to occur if necessary.

4) All data sources external to the box singularly funnel into the system for ease of connectivity and speed of processing to further enhance the flexibility and employment capability of the unit, while not altering the external configuration of the unit.

5) Monitoring of all pertinent components within the box is available via an output data interface available real-time or delayed for post mission analysis which also functions in combination with external interfacing data sources providing an integrated solution for monitoring if necessary.

6) The inherent design philosophy and implementation enables full flexibility for upgrades at the most minimal cost possible while maintaining superior system availability due to the ease which modifications can be employed on a real-time basis.

7) By implementing this cutting-edge and never manifested before system, minimum real-estate is required for mounting which in-turn saves space, weight and cost, allowing for more payload aboard the vehicle, and thus greater launch vehicle efficiency.

8) Through all phases of employment, from build-up, system testing or flight, all electrical, mechanical, firmware or software can be adjusted with minimal impact to more finely tune the system to meet changing or dynamic mission requirements.

9) The modular approach to this system allows for connection/disconnection or module additions in any configuration while maintaining the ability to monitor the new configuration instantly without any software modifications.

10) The playing field is leveled for all system users from very small to very large launch providers due to the simplistic design philosophy that permeates this system on all levels, namely the single-box approach tremendously saves on all aspects of development and employment, whether being used terrestrially or in a space environment.

11) Monitoring and control of the box from any location, close by via hardwire or remote via telemetry, or a combination of both simultaneously is possible due to common communication protocols used extensively throughout the architecture, and which are transparent to module configuration or purpose.

12) Corrective actions within the unit can occur either while consciously monitoring or while not being observed due to system functionality and robust backup capabilities.

13) Real-time reconfiguring within software is employed internally or externally via command if there are any last-minute mission changes which may need accommodation, either pre-anticipated or not.

14) Mission success as well as safety is paramount in the design to preclude a simple non-lethal error from permeating throughout the system and subsequently causing uncontained damage which could endanger the mission.

15) One box, and one set of system qualification criteria is the guideline which distinguishes this box from any and all other multiple box systems whereby internal components can be modified and not impact any other systems external to the box, enabling only a simple and inexpensive incremental system re-qualification, even if it is necessary at all.

16) Proven components integrated into a completely open modular design result in minimal impact when upgrading of the system is desired, and completely negates any possible complications which might have ordinarily occurred with multiple box systems where operational unknowns/errors can occur between boxes due to modifications occurring within one.

17) The resultant shrinking of the space and weight required by this system when compared to current other systems always leaves the door open to further compression as components become smaller, and thus the capability of this system continually increases as newer technologies become available and integrated into any new system requirements which may develop, in complete contrast to the current federated systems approach of others which never benefits from new technology which cannot be retrofitted to their existing federated boxes.

18) The integrated and consolidated skeletal approach applied to the design of this invention subsequently makes all internal and external components of the box a part of the overall integrated functioning system, and as such immediately allows for analysis to occur for assessing the dynamic impacts resulting from any changes of any components in any configuration, and thus provides an instant complete understanding of the resultant new contemplated configuration during any phase of operation.

19) By integrating all the functional aspects of data processing, communications, RF and power into one stack, unmatched efficiencies are obtained in all assembly and testing phases encountered during employment of the system.

20) The developmental efforts resulting in a robust design allowing for routine employment in the most harsh environments provides leveraging for use in more benign atmosphere environments at very little or no additional cost to the using entity.

21) Timelines are greatly condensed with a one box vs. many box approach when it comes to qualification testing, saving funds and allowing for employment to occur much earlier than presently encountered with all existing aerospace systems attempting to do the same functions as this invention.

22) The nature of all federated/only partially integrated modular avionics systems is that they ended up being multiple black-box systems because their designers were never were able to determine the method necessary of how to integrate RF devices with power, processor, data communication and I/O subsystems into a single box system, in complete contrast to this invention which solved the unknowns which led to the ability to contain all functions within one singe integrated structural stack.

23) The individual faraday cage concept in each module combined with a 3D stacking interconnect system between modules allows for complete flexibility to incorporate any combination of RF (wireless communication), processor, data communication and I/O and power subsystems within that module, while simultaneously employing the tongue in groove stacking concept which provides instant rigidity allowing for the most difficult environmental space qualification tests to be passed easily, including shock and vibration.

24) The design philosophy which keeps all wiring within the interior of the modules and structure also contributes to the ease of employment, simplicity of qualification testing, quick interconnectivity, RFI/EMI shielding and its instant use in cross-cutting applications such as those required for a stand-alone satellite, all in a manner that no federated black-box designs or applications can even begin to contemplate applying.

25) The ability to employ this invention instantly within benign atmospheric conditions, up to and including the extreme environment of space is unprecedented and not practical with any and all existing black-box aerospace systems, and demonstrates the stark contrast between this invention and all which have gone before.

26) The virtues of this invention completely serve the need of having a responsive space satellite system that is small in size and thus extremely survivable when compared to their much larger existing system counterparts that are extremely costly and not adaptable for any other uses.

### CONCLUSION, RAMIFICATIONS AND SCOPE

It is evident from the above description that the combination of virtues embodied in this invention are unsurpassed by anything available in the aerospace or any industry, and it serves to forge a new dimension and paradigm when it comes to the assemblage of components which comprise a system which can function equally as well on vehicles operating within benign atmospheric conditions either terrestrially or not, up through and including the harsh environment of space. For the first time in the aerospace or any industry, the data acquisition, computational and system interfaces are of a nature whereby the physical containment structure is integral with the components that comprise it within a single assembled box system, and reside in it to make the whole system an integrated and consolidated system versus existing systems where the physical outer structures of many black boxes are merely a containers to house components in a distributed, non-integrated way.

Of further note with this invention is the unprecedented ability to take its assembled completed configuration and have the utmost ease of flexibility when integrating it into any existing aerospace or other system technology, thereby enabling the simple replacement of the cumbersome, costly and difficult to maintain array of black boxes currently employed in all aerospace and other platforms such as aircraft, spacecraft, missiles, rockets and the like. Additionally, the ease of incremental or full upgrades to this fielded invention also paves the way for extreme employment and modification cost reductions on a global scale, with no other federated/only partially integrated modular systems used today even remotely coming close to the capabilities made instantly possible with this invention. Additionally;

It provides predictable, reliable and monitorable operation through all aspects of employment in all defined environments the system is expected to function in, from the benign atmospheric conditions of earth, up to and including transit into the harsh environment of space, and has great reserve to function without any modification when expected tolerances are exceeded.

It affords comprehensive system protection from unintentional mishaps which may occur during any phase of operation, and depending on the incident, provide an automated course of action or make the opportunity available for rapid repair/replace methods to be implemented which include simple module replacement, or components within the module to be replaced extremely rapidly, and without any impact to adjacent systems.

It enables full operational confidence to be achieved during all phases of the mission by providing a constant suite of measurements via hardwire or telemetry anytime the system is powered on, while also performing continual internal diagnostics that can enable a rapid recovery into a backup mode if the primary system encounters difficulties.

It is capable of ingesting or outputting data in an extremely simple and robust way through standard connectors and protocols, thus substantiating a system flexibility enabling the greatest ease of configurability and simple integration into any vehicle where replacement of any federated black box system is desired.

It offers the instant ability to monitor and troubleshoot any systems or configurations within the box via standard output connectors/protocols, and provide that data along with mission data to a common collection and analysis interface point whether the vehicle is on the ground or in operation in any environment.

It functions in a flexible manner allowing incremental or full system upgrades at any time, which also includes entire module interchanges on a moments notice without exposing the system to any operational or configuration control complexities or risks, while lending itself to the rapid repair and re-fielding of a suspect module in an unprecedented rapid timeframe, currently unknown in the aerospace industry.

It offers the critical benefits of unprecedented reduced size, weight and power consumption while simultaneously and exponentially increasing the reliability and processing power of the system it is integrated into, all within a much smaller and incomparable space than previous other black box systems occupied.

It is instantly adaptable to any sudden changes in mission needs, and allows for unprecedented rapid access to components internal to the modules, as well as on an exo-modular level when only full module replacement is required in a timely manner.

It employs easily reconfigurable automated software which functions in a ‘plug and play’ fashion to instantly and automatically recognize and redefine all interfaces necessary to adapt to any new required configuration.

It is usable on all aerospace and other vehicles from large to small, complex to simple, and is instantly adaptable to migrate between any of these vehicles at any time, whether being employed within benign atmospheric earth type conditions or the harsh environment of space.

Its modular design allows for unprecedented insight into a system of this type whereby all internal and external systems related to the box can be analyzed remotely during any phase of its operation while using a standard windows-type of graphical user interface.

It comes from a robust design philosophy whereby capabilities flow downward to manifest the most flexible and unprecedented system with full traceability of all internal systems, including a mapping of all interfaces and pathways for redundant operation.

It includes automated methodology which recognizes states requiring adjustment, and implements last minute changes in pre-flight or flight scenarios whether or not commanded externally, and reconfigures all pertinent on-board systems to accommodate the new mission requirements as required.

It leverages fault-tree logic methods into its physical design, and captures them in its software to insure that all module configurations are isolated from any possible migrating anomalies, whether from internal or external sources, which could jeopardize mission success or safety.

Its built-in nature of instant module access resulting in instant reconfigurability, either internally or externally, emulates a multiple box system's tolerance and robustness while advancing the benefits of sustained reliability and operational effectiveness that minimizes the required assembly, qualification testing, employment hours and related costs to that of a multiple black-box system.

It is capable of adding or leveraging special or customer driven unique independent design solutions into a single box system with a completely open architecture, allowing for desired or minor changes or mandatory upgrades to be accomplished within established interfaces, and thereby precluding any unanticipated interactions between components or modules or even multiple systems which may be networked together.

It has an ability to integrate new components or systems within its existing internal or external structure, or even be the catalyst for creating a new generation of smaller technological structures utilizing the blueprint of governing factors presently defined by this invention.

It makes it possible to leverage the design philosophy of this invention whereby all aspects of the box infrastructure are an active part of the single box design, and are constantly monitored through all mission phases for any product-improvement that may be necessary.

It enables rapid employment by presenting only one integrated and consolidated box for all qualification testing and installation into the vehicle and for use in subsequent operation.

It can be cost-effectively employed in any application, from aircraft, to spacecraft, to launch vehicle, or terrestrial vehicle in a rapidly employable manner while leveraging design and hardware benefits which can accommodate the harshest of environments.

It employs the simplest and most cost effective qualification testing for only one integrated box, in contrast to the many federated ones which are now employed on all fielded aerospace systems to achieve the same capability of the one box approach defined by this invention.

It is the first invention of its kind that is truly scalable and modular due to addressing all the components that must be considered for integration into a truly integrated box, whereby vibration, shock and RFI/EMI are considered along with accommodating internal RF devices.

It integrates two shock and vibration immune faraday cages within each modular structure that seals when either a module is place above another one, or an end-cap is secured above a module, with the entire stack being an open architecture that can be expanded or condensed without any preset limits.

It has an interconnecting modular raceway system which separates at the module level, and allows for a single complete faraday cage to be formed, running the complete height of the system for containing the internal raceway, and thus all power and communications are shielded from all components in the adjacent module faraday cage which contains all installed system components.

It demonstrates that cost can be greatly reduced in aerospace systems by employing a single integrated box for all functions while being instantly and cost effectively employed in practically any scenario without any modification.

It enables an unprecedented level of survivability and operability, especially when employed in a space environment as a stand-alone satellite system that is of an almost undetectable size, and is yet as capable and functional as its much larger predecessors.

The many detailed descriptions above must not be interpreted in any manner to indicate a limit to the scope of this invention, as its only intent is to provide examples of its functionality obtained by employing it in standard configurations. For example, the IMATS may contain any number of partitioned internal RFI/EMI chambers and raceways. Although many specifics have been contained therein to help describe the functioning of this system in a simple modular way, they should not be construed to confuse the main aspect of this invention that is the application of complete scalability, modularity, open architecture, flexibility, stackability, interconnectivity, reconfigurability, adaptability, interchangeability and consolidation in a single unit system which takes the place of many boxes comprising all existing avionics or other types of technology systems functioning terrestrially on through the environment of space.

Additionally, for the first time in the history of the aerospace industry, no longer will there be a reliance upon distributed unique black-box systems which very inefficiently provide the functions of TSPI, DA/P/R, PG/D, wireless communication, avionics, navigation, command and data handling, and are certainly not adaptable into becoming a stand-alone deployed satellite system. Additionally, these traditional black-box systems are of a nature whereby their internal components are simply housed in a uniquely fabricated box structure, opposed to the essence of this invention whereby a mass-producible and repeatable structure is utilized whereby the integrated and consolidated system is that of an inner and outer single structure which together comprises the totality of the complete system, including the capability to provide RFI/EMI shielding on a modular level, as well as an integrated box system level, while easily passing all required environmental qualification testing including shock, vibration, thermal and the like. Thus, the scope of this invention should only be determined by the appended claims and their legal equivalents.

(i) All present federated/only partially integrated modular aerospace hardware and avionics systems negate the possibility of morphing their configuration into a modular stackable and reconfigurable type system, either in a physical or electrical arrangement, thus increasing their design, implementation and qualification costs.

1.-8. (canceled)

9. A multi faraday cage system contained within a single enclosure comprising:
a container having an open ended top, a bottom, and integral contiguous walls between said open ended top and said bottom, the perimeter edge of said integral contiguous walls defining the opening of said open ended top, said container being formed of an EMI/RFI resistant material;
said open ended top and said bottom of said container having an oppositely alternating container tongue and groove means circumferentially around the perimeter edge of said container open ended top and said container bottom,
a separately formed container top with a container top tongue and groove means which accepts said container tongue and groove means around said open ended top to integrally form an interference fit therein and create an integral EMI/RFI sealed and resistant assembly comprising said container top mated to said open ended top,
a separately formed container base with a tongue and groove means that accepts said tongue and groove means of said container bottom to integrally form an interference fit therein and create an integral EMI/RFI sealed and resistant assembly comprising said container base mated to said container bottom,
a fastener means simultaneously securing said container top to said integral contiguous walls, said container bottom and said container base, further compressing, environmentally and EMI/RFI sealing and interlocking said tongue and groove means together of said container top, said container open ended top, said contiguous walls, said container bottom and said container base, while simultaneously minimizing the destructive effects of mechanical shear on said EMI/RFI resistant assembly,
said container being internally sub-dividable into adjacent single faraday cages via use of EMI/RFI resistant sub-walls employing a tongue and groove means interfacing with a corresponding tongue and groove means in said container top, said container bottom and said container base, while forming an adjacent tongue and groove connection with said container's integral continuous walls,
said container top, said container's integral contiguous walls, said container bottom, said container base and said EMI/RFI resistant sub-walls allowing for a conductive penetrating means to accomplish routing and interfacing of electrical data and optical communication, power, and radio frequency signals including an antenna means into and out of said adjacent faraday cages while maintaining EMI/RFI isolation of all said adjacent single faraday cages,
said bottom of said container selectively having an integral EMI/RFI sealed floor with an interior and exterior surface being integrally and contiguously formed and adjacent to said integral contiguous walls and said sub-walls, said bottom of said container selectively having an open floor being EMI/RFI sealed by said container base, in combination with said contiguous sub-walls and said contiguous walls.

10. A container as being claimed in of claim 9 being interchangeably stackable with any number of identical said containers in an interchangeably stackable and reconfigurable fashion, with said container tongue and groove means forming an interference fit whereby said exterior surface of said integral EMI/RFI sealed floor of said container bottom situated above forms an EMI/RFI resistant top lid for said open ended top container situated below in combination with said fastener means selectively securing any number of stacked identical said containers,
the top-most open ended top container of the plurality of interchangeably stacked said containers being covered by said container top having said container top tongue and groove means integrally accepting and forming an interference fit therein with said open top container tongue and groove means, creating an integral EMI/RFI sealed and resistant container top in combination with said open ended top,
said tongue and groove means of said bottom of the bottom-most container in the plurality of stacked said containers being secured to said tongue and groove means of said separately formed container base to form an interference fit therein and create an integral EMI/RFI sealed and resistant container base in combination with said container bottom,
said open floors of said containers collectively and selectively forming a longitudinal faraday cage system traversing a selected plurality of interchangeably stacked said containers, said longitudinal faraday cage system comprised of said integral contiguous walls and said contiguous sub-walls being EMI/RFI secured into a faraday cage system in adjacency to said interior and exterior surfaces of said integral EMI/RFI sealed floors, said container top and said container base,
said fastener means simultaneously securing said container top to said integral contiguous walls, said container bottom and said container base, further compressing, environmentally and EMI/RFI sealing and interlocking said tongue and groove means of all said stacked identical said containers, container top and container base, while simultaneously eliminating the destructive effects of mechanical shear on said EMI/RFI resistant assembly,

11. The collectively formed longitudinal faraday cage system of claim 10 having an internal raceway extending a selective length throughout said plurality of interchangeably stacked said containers to interconnect, interface and route electrical data, optical communication, power, and radio frequency signals in any combination between any said internally subdivided container defining said single faraday cage with any other said faraday cage in any other said container, while employing said conductive penetrating means of said sub-walls allowing access to electrically interconnect said faraday cages and said internal raceway in any combination.

12. A multiple faraday cage system of claim 9 whereby processor, electrical, RF and optical communication, power, radio frequency, and sensor component means are placed within said single faraday cages and selectively interconnected, interfaced and electrically routed to processor, electrical, RF and optical communication, power, radio frequency, and sensor components within any other said adjacent single faraday cage via said conductive penetrating means of said sub-walls.

13. A faraday cage of claim 10 whereby processor, electrical, RF and optical communication, power, radio frequency, and sensor component means are placed within a first said faraday cage and selectively electrically interconnected, interfaced and routed to processor, electrical, RF and optical communication, power, radio frequency, and sensor components within a second said adjacent single faraday cage via said conductive penetrating means of said sub-walls, while further allowing for electrical connectivity between non-adjacent faraday cages within said container.

14. A faraday cage of claim 13 whereby processor, electrical, RF and optical communication, power, radio frequency, and sensor component means are placed within said faraday cage and electrically interconnected to said internal raceway via said conductive penetrating means of said sub-walls to interconnect, interface and route electrical pathways to other said processor, electrical, RF and optical communication, power, radio frequency, and sensor components located in any other non-adjacent said faraday cages within any said stacked containers in any arrangement via said internal raceway in combination with said penetrating means of said sub-walls.

15. A faraday cage of claim 9 whereby a non EMI/RFI resilient component such as a propulsion and attitude pointing means is mechanically coupled within said container of said single enclosure for externally propelling and orienting said single enclosure in any combination of the X, Y or Z-axis while maintaining the EMI/RFI integrity of said adjacent faraday cage and all other said faraday cages comprising said single enclosure.

16. A faraday cage of claim 14 whereby a non EMI/RFI resilient component such as a propulsion and attitude pointing means is mechanically coupled within said container of said single enclosure for externally propelling and orienting said single enclosure in any combination of the X, Y or Z-axis while maintaining the EMI/RFI integrity of said adjacent faraday cage and all other said faraday cages comprising said single enclosure; whereby a completely modular, stackable, scalable, reconfigurable and open architecture multi faraday cage system is made possible from the smallest component faraday cage dimension up to and including the collective grouping of said multiple faraday cages contained within said single enclosure.
